(19) United States
(12) Patent Application Publication
(10) Pub. No.: US 2026/0173253 A1
(43) Pub. Date: Jun. 18, 2026

(54) RADIO FREQUENCY FRONT-END MODULE WITH EMBEDDED CIRCULATORS

(71) Applicant: TTM Technologies North America, LLC., St. Louis, MO (US)

(72) Inventors: Theodore Bullen, Webster, MA (US); Thomas Lingel, Cazenovia, NY (US); Lorenzo Lo Monte, Huntington, NY (US)

(21) Appl. No.: 19/424,743

(22) Filed: Dec. 18, 2025

Related U.S. Application Data
(60) Provisional application No. 63/735,732, filed on Dec. 18, 2024.

(51) Int. Cl. H05K 1/02; H01F 7/02; H01P 1/38; H03F 3/24; H04B 1/00; H04B 1/48

(52) U.S. Cl. CPC H05K 1/0243; H01F 7/02; H01P 1/38; H03F 3/245; H04B 1/48; H03F 2200/451; H04B 1/006; H05K 2201/10734

(57) ABSTRACT

The disclosure provides a design of integrating a ferrite-based circulator within the surface mount device (SMD) package for an RF front-end module. The ferrite-based circulator serves as a duplexer. The front-end module contains all relevant transmitting/receiving (T/R) functions within a small footprint having significant power handling. The disclosed front-end module can be interfaced with Analog-to-Digital and Digital-to-Analog converters.

### CROSS-REFERENCE TO RELATED PATENT APPLICATION

This patent application claims the benefits under 35 U.S.C. § 119(e) of U.S. patent application Ser. No. 63/735,732, entitled “RADIO FREQUENCY FRONT-END MODULE WITH EMBEDDED CIRCULATORS,” filed on Dec. 18, 2024, which is incorporated herein by reference in its entirety.

### FIELD

The disclosure is directed to the design and methods for fabricating an RF (Radio Frequency) front-end module with embedded circulators. In particular, the RF front-end module is integrated with the circulators serving as duplexers for antennas.

### BACKGROUND

Circulators are widely used devices in radar systems or power amplifiers. The circulators provide non-reciprocal functionality that is essential for duplexing applications, amplifier protection or non-coherent signal combining. Circulators realize non-reciprocal functionality by using specific microwave ferrite materials. The properties of these materials are controlled via a DC magnetic bias field. Circulators are traditionally 3-port devices. When power is injected into port 1, most power exits port 2. When power is injected into port 2, most power exits port 3. When power is injected into port 3, most power exits port 1.

Circulators utilize specialized microwave ferrites that are good insulators and allow for a low-loss propagation of RF signals through the ferrites. The ferrites are ceramic-like materials typically based on the formulation of iron oxide (Fe₂O₃) and are soft magnetic. The ferrites are magnetically biased by a static magnetic bias field, which sets the properties (e.g., permeability) of a radio frequency (RF) tensor that enables the non-reciprocal operation of a device. Permanent magnets usually provide the static bias field. Common commercial magnets include Ceramic magnets, Aluminum-Nickel-Cobalt (AlNiCo) magnets, or rare earth materials like Samarium-Cobalt (SmCo) magnets or Neodymium-Iron-Boron (NdFeB) magnets.

The circulator can be designed with either clockwise (CW) or counterclockwise (CCW) operation by changing the polarity of the magnetic bias field. The direction is set by the orientation of a statically applied magnetic bias field. In a clockwise circulator, if a signal is applied to a port, then the signal will exit the next port in a clockwise direction while the next port in a counterclockwise direction is isolated, i.e., the next port receives no signal, and vice versa if the circulator is in a counterclockwise direction.

One of the most popular circulators is a Y-junction circulator, such as a single-junction circulator having three ports or a double-junction circulator having four ports. The 3-port circulator has three branches extending symmetrically outward from the central conductive portion, ideally 120° apart from each other. Additional components, including permanent magnets, pole pieces, and housings, are necessary for the overall operation of the device. Often, a steel housing is utilized as a magnetic return path.

Circulators are widely used on radio frequency (RF) systems as duplexers to simultaneously transmit and receive through a common antenna. An active electronically scanned array (AESA) is a type of phased array antenna, which is a computer-controlled antenna array in which the beam of radio waves can be electronically steered to point in different directions without moving the antenna. In the AESA, each antenna element is connected to a transmit/receive front-end module, which is controlled by a controller to perform the functions of the transmitter and/or receiver for the antenna. AESA is used in radar, often called active phased array radar (APAR).

Conventional surface mount front-end modules utilize T/R (transmitting/receiving) switches, such as positive-intrinsic negative (PIN) diodes, to ensure miniaturization and area fit within a prescribed package. However, miniaturization may result in reduced performance. When sizes become an issue, such as in modern AESAs that need front-end modules to be small in size or weight, the T/R switches in front-end modules cannot offer the performance.

The T/R switches function as lower performing or lower capable duplexers, although the size is small. Specifically, the switching-based duplexing has several performance drawbacks as follows. First, switching elements (e.g., PIN diodes) are active components exhibiting a far shorter mean time between failures (MTBF) than passive ferrite-based circulators. The MTBF is the average time between product failures. The metric is used to track the reliability of a product. The product is more dependable when the time between failures is longer. Second, switching elements exhibit high losses, typically three times higher than an equivalent circulator solution. Third, even multiple T/R switches cannot protect the transmitter from high-intensity RF (HIRF) fields, while a dual junction circulator diverts HIRF to a passive load. Fourthly, T/R switches do not allow simultaneously transmitting and receiving signals, also referred to as full duplex operation. Although the full duplex is rare in radar systems, the full duplex mode is quite common in communication systems.

The circulator-based duplexers have some benefits over the T/R switching-based duplexers. First, circulator-based duplexers can manage higher power levels than conventional switching elements or switches, which require special design considerations. Second, circulator-based duplexers guarantee reduced transmit power output variation as a function of scan angle, due to improved impedance matching conditions between power amplifier and antenna elements (i.e., circulators effectively function as “isolators”). Third, circulator-based duplexers redirect unwanted reflected power from Rx (receiver) or Tx (transmitter) to a passive load, preventing the scattering of undesired signals. Fourth, circulator-based T/R front-end modules may simplify the design of pre-selector filters, leading to fewer losses and better out-of-band protection.

There remains a need to develop front-end modules for AESAs that use front-end modules with miniaturization and improved performance.

### BRIEF SUMMARY

In one aspect, a surface mounting device is provided for transmitting or receiving signals from one or more antennas. The surface mounting device may include one or more circulators embedded within a laminated circuit board. The surface mounting device may also include the one or more circulators coupled to the one or more antennas and serving as duplexers. The surface mounting device may also include one or more magnets attached to a first mounting surface of the laminated circuit board; one or more radio frequency (RF) amplifiers coupled between the one or more circulators and one or more transmitters. The surface mounting device may also include one or more circuit components coupled between the one or more circulators and one or more receivers. The surface mounting device may also include ball grid array (BGA) solder balls on a second mounting surface of the laminated circuit board, the second mounting surface being opposite to the first mounting surface.

In some aspects, the one or more RF amplifiers may be attached to the first mounting surface or embedded within the laminated circuit board.

In some aspects, the one or more RF amplifiers may include power amplifier and/or driver amplifier.

In some aspects, the one or more circuit components may be attached to the first mounting surface or embedded within the laminated circuit board.

In some aspects, the one or more circuit components may include a low noise amplifier and/or limiter.

In some aspects, the one or more magnets may include one of Ceramic magnets, Samarium-Cobalt magnets (SmCo) magnets, Aluminum-Nickel-Cobalt (AlNiCo) magnets, or Neodymium-Iron-Boron (NdFeB) magnets.

In some aspects, the surface mounting device may include one or more RF connectors attached to the first mounting surface of the laminated circuit board and configured to receive signals or transmit signals from the one or more antennas.

In some aspects, the one or more circulators may include single junction circulators.

In some aspects, the one or more circulators may include stacked double junction circulators.

In some aspects, the surface mounting device may include a termination feature.

In some aspects, the termination feature may be embedded within the laminated circuit board.

In some aspects, the termination feature may be mounted on the first mounting surface of the laminated circuit board.

In some aspects, the surface mounting device may be a surface mount module on a printed circuit board.

In some aspects, the surface mounting device may be suitable for radio frequency applications.

In some aspects, the radio frequency applications may include active electronically scanned array (AESA) applications.

In another aspect, a method is provided for fabricating a surface mounting device configured for transmitting or receiving signals from one or more antennas. The method may include embedding one or more circulators within a laminated circuit board including a plurality of dielectric layers interleaved with a plurality of conductive layers, the one or more circulators coupled to the one or more antennas and serving as duplexers. The method may also include attaching one or more magnets to a first mounting surface of the laminated circuit board. The method may also include forming one or more radio frequency (RF) amplifiers coupled between the one or more circulators and one or more transmitters. The method may also include forming one or more circuit components coupled between the one or more circulators and one or more receivers, wherein ball grid array (BGA) solder balls are formed on a second mounting surface of the laminated solder balls circuit board opposite the first mounting surface.

In some aspects, the method may also include attaching the one or more circuit components to the first mounting surface or embedding the one or more circuit components within the laminated circuit board.

In some aspects, the method may also include attaching the one or more RF amplifiers to the first mounting surface or embedding the one or more circuit components within the laminated circuit board.

In some aspects, the method may also include embedding one or more directional coupler within the laminated circuit board, wherein the one or more directional coupler is coupled between the one or more circulators and the one or more antennas.

In some aspects, the method may also include bonding two adjacent dielectric layers using fusion bonding or using a liquid resin or prepreg material.

Additional aspects and features are set forth in the following description and will become apparent to those skilled in the art upon examination of the specification or may be learned by the practice of the disclosed subject matter. A further understanding of the nature and advantages of the disclosure may be realized by reference to the remaining portions of the specification and the drawings, which form a part of this disclosure.

### BRIEF DESCRIPTION OF THE DRAWINGS

The description will be more fully understood with reference to the following figures and data graphs, which are presented as various embodiments of the disclosure and should not be construed as a complete recitation of the scope of the disclosure, wherein:

FIG. 1A is a simplified diagram for a conventional front-end module with a transmit/receive (T/R) switch (prior art);

FIG. 1B is a simplified diagram for a conventional front-end module with an external circulator (prior art);

FIG. 2 is a system diagram including a front-end module with an integrated circulator according to one aspect of the disclosure;

FIG. 3 is a simplified diagram showing a circulator and other components embedded/mounted with a laminated circuit board according to one aspect of the disclosure;

FIG. 4 is a diagram showing multiple building blocks on a single laminated circuit board in a BGA package according to one aspect of the disclosure;

FIG. 5A is a block diagram for front-end module using a single junction circulator according to one aspect of the disclosure;

FIG. 5B is a block diagram for front-end module using a double junction circulator with one circulator in a receiving path according to one aspect of the disclosure;

FIG. 5C is a block diagram for front-end module using a double junction circulator with one circulator in a transmitting path according to one aspect of the disclosure;

FIG. 6A is a top layout view of an RF front-end module including a circulator according to one aspect of the disclosure;

FIG. 6B is a cross-sectional view of a laminated circuit board of the RF front-end module of FIG. 6A including an embedded double junction circulator according to one aspect of the disclosure;

FIG. 7A is a top view of an RF front-end module including four building blocks configured for four antennas according to one aspect of the disclosure;

FIG. 7B is a perspective view of the RF front-end module of FIG. 7A including four connectors configured for four antennas according to one aspect of the disclosure;

FIG. 8 is a perspective view showing ball grid array (BGA) on the opposite side of the laminated circuit board of FIG. 7B from surface mount device (SMD) components and wire components according to one aspect of the disclosure; and

FIG. 9 is a stacked double junction circulator for use in the RF front-end module of FIG. 6B according to one aspect of the disclosure.

### DETAILED DESCRIPTION

The disclosure may be understood by reference to the following detailed description, taken in conjunction with the drawings as described below. It is noted that, for purposes of illustrative clarity, certain elements in various drawings may not be drawn to scale.

The disclosure provides a design of integrating a ferrite-based circulator within the surface mount device (SMD) package for an RF front-end module. The ferrite-based circulator serves as a duplexer. The front-end module contains all relevant transmit/receive (T/R) functions within a small footprint having significant power handling. The disclosed front-end module can be interfaced with Analog-to-Digital Converters (ADC) and Digital-to-Analog Converters (DAC) converters. The disclosed RF front-end modules are applicable to all AESA systems, regardless of radar or communication systems.

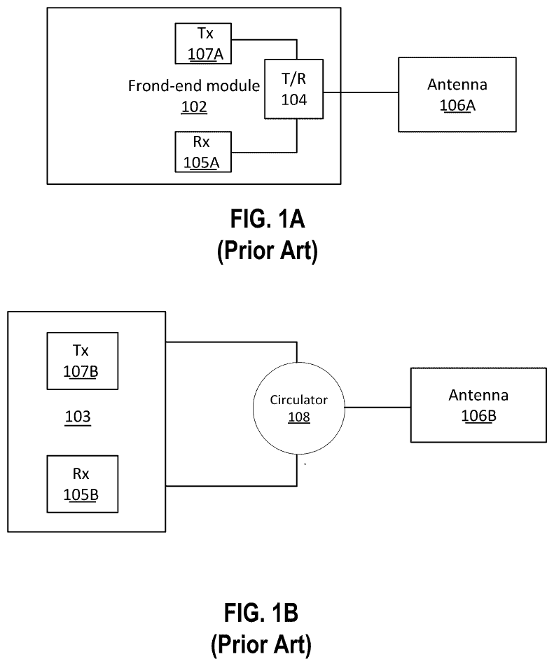

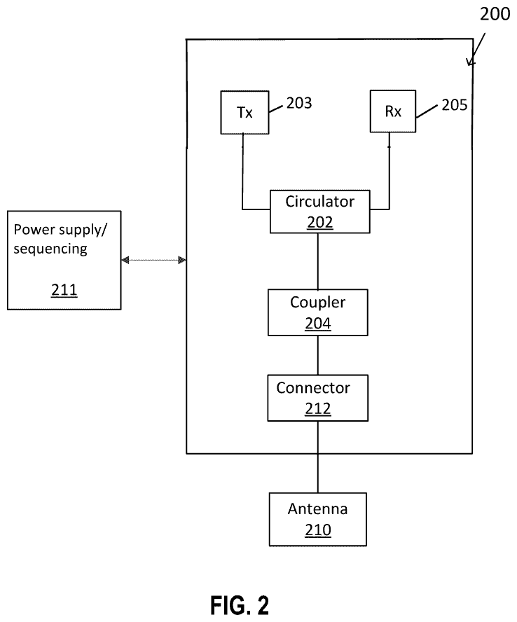

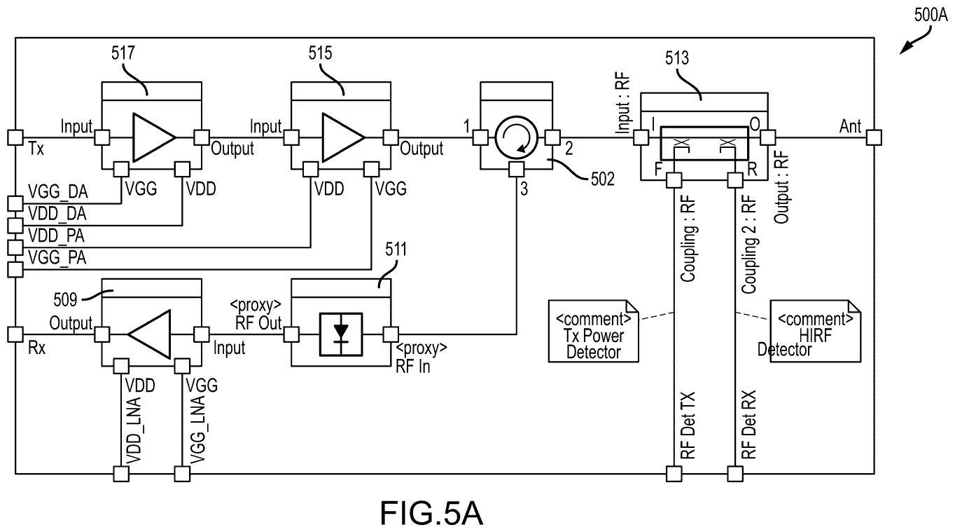

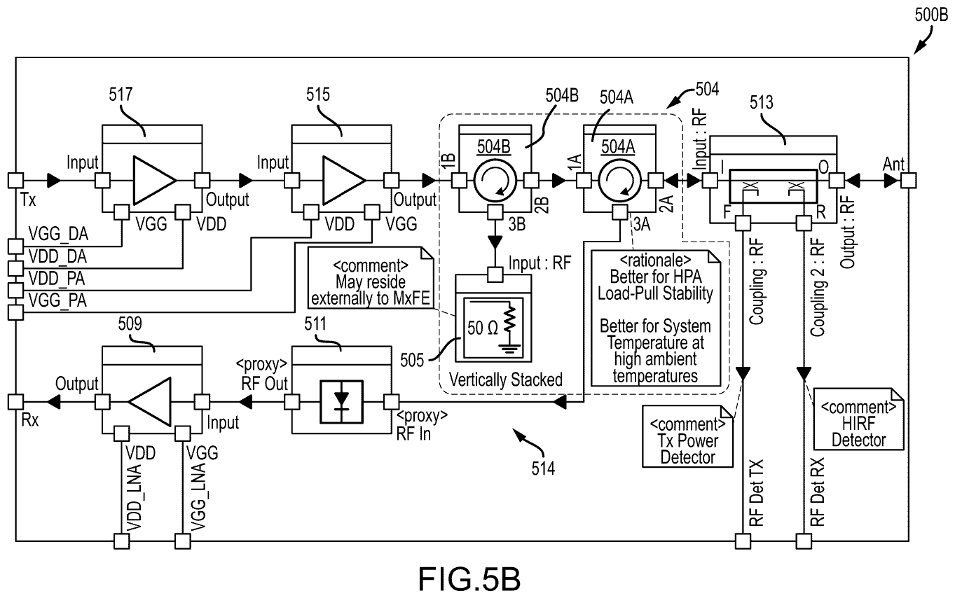

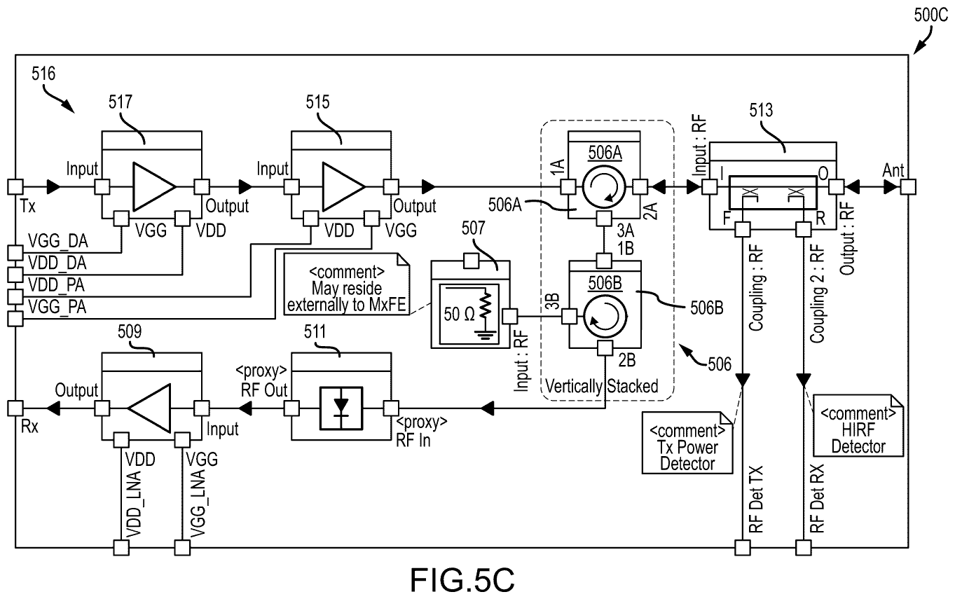

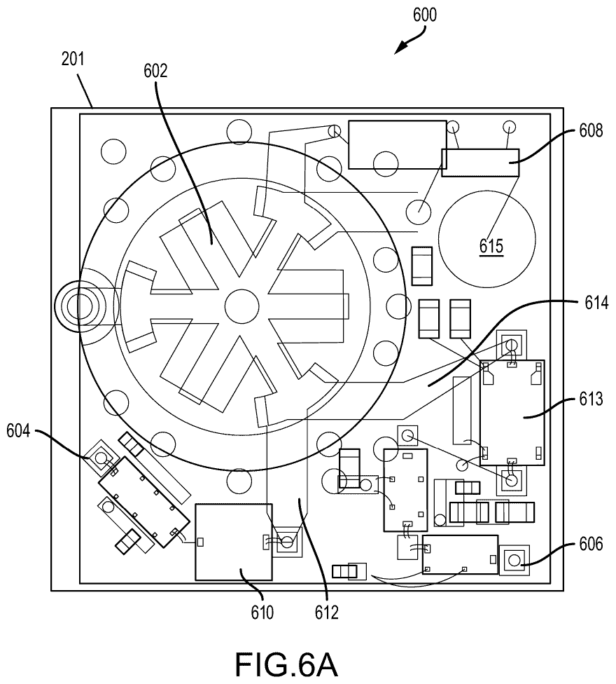

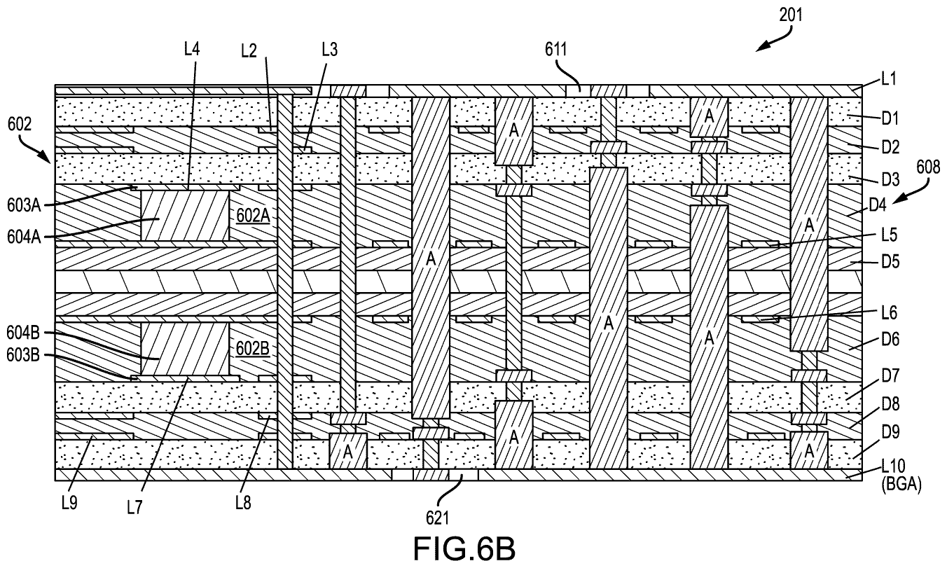

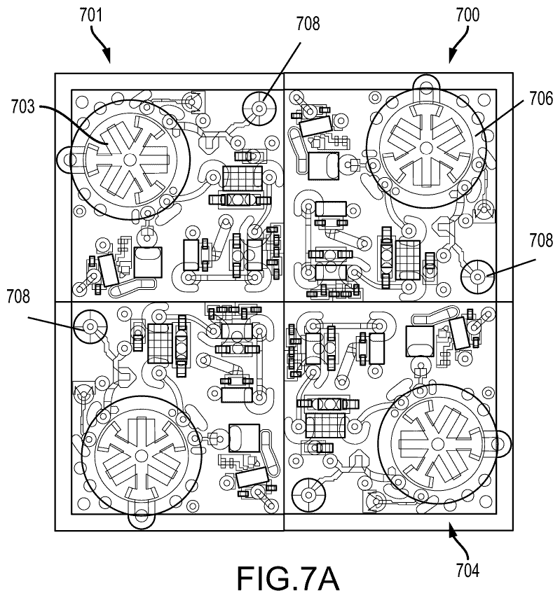

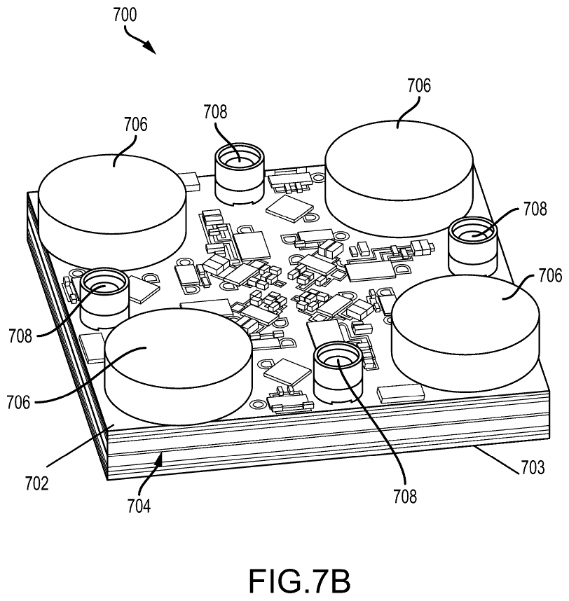

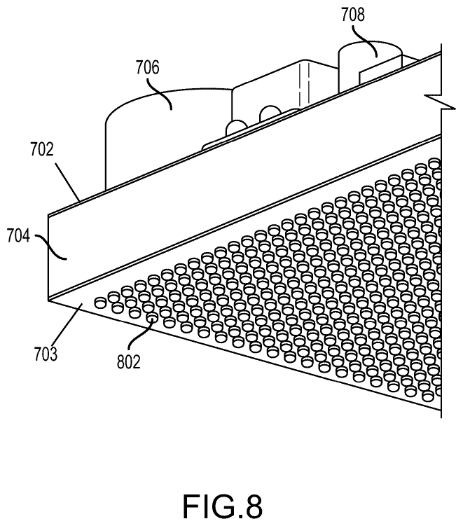

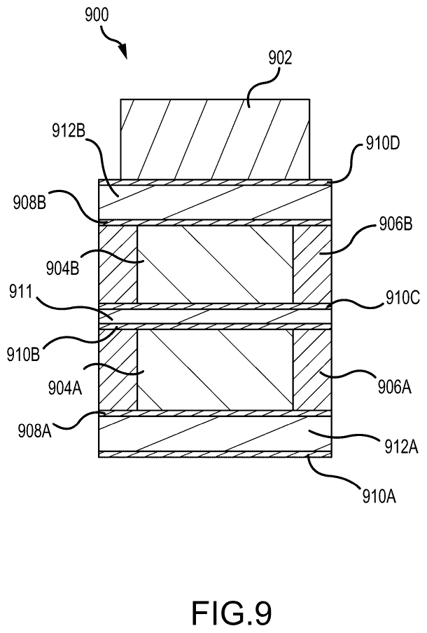

The disclosure describes conventional front-end modules, as illustrated in FIG. 1A and FIG. 1B. The disclosure also describes the present front-end modules that are different from the conventional ones, as illustrated in FIGS. 2-4. The disclosure provides various configurations of the front-end modules, as illustrated in FIGS. 5A-5C. The disclosure also provides examples, as shown in FIGS. 6A-6B, for a front-end module including a double-junction circulator. The disclosure also provides examples, as shown in FIGS. 7A-7B, for a front-end module including multiple double-junction circulators. FIG. 8 shows a front-end module configured to be a surface mount device and configured to connect to antennas. The disclosure also illustrates an example of a double junction circulator in FIG. 9.

FIG. 1A is a simplified diagram for a conventional front-end module (prior art). As shown in FIG. 1A, a T/R front-end module 102 includes a receiver (Rx) 105A and a transmitter 107A. T/R front-end module 102 also includes a T/R switch 104 that is connected to an antenna 106A. The T/R switch 104 is coupled to the receiver (Rx) 105A and the transmitter (Tx) 107A and serves as duplexer. The T/R switch may also be integrated with the T/R front-end module 102. However, miniaturization may result in reduced performance.

In some cases when performance is important, front-end modules are created without the duplexer function. The front-end modules may use external circulators (e.g., ferrite-loaded circulators) as duplexers. FIG. 1B is a simplified diagram for a conventional front-end module with an external circulator (prior art). As shown in FIG. 1B, a front-end module 103 includes a receiver (Rx) 105B and a transmitter 107B. The front-end module 103 is connected to an external circulator 108, which is coupled to antenna 106B. The external circulator 108 serves as duplexer but is not an integrated part of the front-end module 103.

The external circulator 108 (e.g., ferrite loaded circulator) is not integrated with the front-end module 103, although the external circulator also realizes advantages above for the circulator-based duplexers. The duplexing function through the external circulator 108 requires more PCB (Printed Circuit Board) allotment. The solution with non-integrated circulator is non-miniaturized.

The disclosure addresses the issues of meeting the need of size reduction without sacrificing the performance by providing a front-end module that uses embedded circulators as duplexers. The circulators may be ferrite-based and embedded within a surface mount package, e.g., BGA (Ball Grid Array). The disclosed front-end module enables the use of circulator-based duplexing within BGA SMD (Surface Mount Device) packaged transmit/receive front-end modules. The disclosed front-end module is circulator-based, and also is BGA SMD packaged.

The disclosed front-end module is different from that disclosed in U.S. Pat. No. 9,172,145, entitled “TRANSMIT/RECEIVE DAUGHTER CARD WITH INTEGRAL CIRCULATOR,” by Angelo M. Puzella, issued Oct. 27, 2015, which discloses a daughter board packaging solution rather than a BGA SMT packaging solution. The daughter board packages are physically large, resembling an integrated microwave assembly, and do not facilitate the miniaturization for BGA SMD processes. U.S. Pat. No. 9,172,145 discloses, in Col. 40, line 12, “a TR daughter card with an integral circulator.” Also, U.S. Pat. No. 9,172,145 discloses, in Col. 40, lines 27-31, “attaching the circulator to a surface of the daughter board opposite a surface having MMICs mounted”. As such, the circulator is on the daughter board, which is separated from the laminated circuit board for mounting MMICs (Monolithic Microwave Integrated Circuits). The circulator is also on the opposite side from the MMICs.

The disclosed front-end module offers sufficient miniaturization for future AESAs designs without compromising the high performance achievable by non-miniaturized solutions. The miniaturization of the disclosed front-end module can offer custom-made, high-quality, high-margin, and high-performance solutions. The disclosed front-end module can be used for AESAs, particularly the small form-factor AESAs or future generations AESAs that may need the miniaturization of transmit/receive front-end modules. For example, a ball grid array (BGA) surface-mounted device (SMD) serves as RF transmit/receive front-end module with at least one integrated ferrite-based circulator for AESA applications.

The disclosed front-end module differs from the conventional front-end module having T/R switch in a single package. The disclosed front-end module uses a circulator to replace the T/R switch in a single package. The circulator is integrated with the front-end module. In particular, the circulator including ferrites is embedded in the laminated circuit board.

FIG. 2 is a system diagram including a front-end module with an integrated circulator according to one aspect of the disclosure. The system includes a front-end module 200, which may include components including Tx (transmitter) 203 and Rx(receiver) 205 to perform various RF functions for transmitting and receiving (T/R) operations. The RF functions include power amplification, low noise amplification, limiting of received high-power signals, duplexing via circulator, and power monitoring via passive couplers, among others. The system also includes a power supply and sequencing circuitry 211 coupled to the front-end module 200 for applying a timed DC bias voltage to the Tx (transmitter) 203 and Rx(receiver) 205 amplifiers pending mode of operation.

The DC bias voltage for the Tx 203 and Rx 205 can be turned on or off by a controller (not shown) to save energy. For example, when the front-end module is used in receiving signal, the power for the transmitter or Tx 203 is turned off. As another example, when the front-end module is used in transmitting signal, the power for the receiver or Rx 205 is turned off.

As shown in FIG. 2, the front-end module 200 may also include a circulator 202 for duplexing. The circulator 202 provides an output to antenna 210 from the signal transmitter (Tx) 203 or a transmitting signal source via a transmitting channel or a transmitting path or provides an input from the antenna 210 to the signal receiver (Rx) 205 via a receiving channel or a receiving path.

The front-end module 200 may optionally include a uni-directional or bi-directional coupler 204 for power monitoring, e.g., monitoring the power received from the antenna 210 or transmitted to the antenna 210. The front-end module 200 may also include receive/transmit connectors 212 configured to connect to antenna 210. The receive/transmit connector 212 is also referred to as an antenna interface.

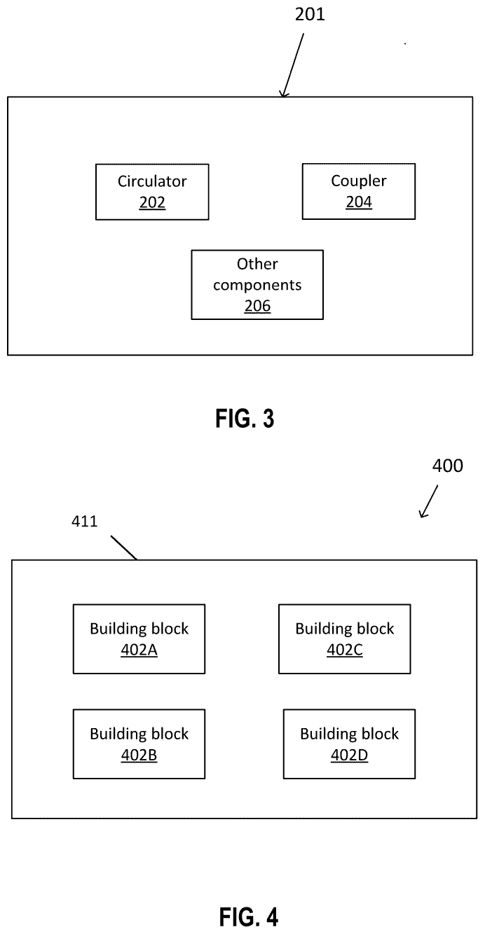

The front-end module 200 may also include a laminated circuit board 201 or a laminated circuit assembly (LCA). FIG. 3 is a simplified diagram showing a circulator and other components embedded/mounted with a laminated circuit board according to one aspect of the disclosure. As shown in FIG. 3, the circulator 202 may be embedded within the laminated circuit board 201. The directional coupler 204 may also be embedded within the laminated circuit board 201. One or more other components 206, such as RF amplifiers, may also be embedded within the laminated circuit board 201. The RF amplifiers may include power amplifiers (e.g., driver amplifier and/or high-power amplifier), or low noise amplifier, among others.

One or more of the RF amplifiers may be mounted on surface on a mounting surface of the laminated circuit board 201. Some other components may also be attached to the laminated circuit boards. For example, magnets for biasing the circulators may be attached to a mounting surface of the laminated circuit board. Also, connectors to the antennas may also be attached to the mounting surface of the laminated circuit board 201. A BGA is on opposite side of the laminated circuit board 201.

In some variations, the circulators may be single junction circulators or double junction circulators.

In some variations, the front-end module 200 may be integrated with surface mountable circulators using two ferrites in a classic stripline configuration, as described in U.S. Pat. No. 8,183,952, entitled “SURFACE MOUNTABLE CIRCULATOR”, by Graeme Bunce et al, issued on May 22, 2012, which is incorporated by reference in its entirety.

In some variations, the front-end module 200 may also be integrated with double junction circulators using a stacked configuration, as outlined in a U.S. patent application Ser. No. 18/629,042, entitled “DESIGN OF STACKED DOUBLE JUNCTION CIRCULATOR DEVICE AND METHODS FOR FABRICATION”, by Thomas Lingel et al, filed on Apr. 8, 2024, which is incorporated by reference in its entirety.

The stacked configuration of the double junction circulators can reduce space requirements. The stacked double junction circulator device may include two ferrites, three ferrites or four ferrites, among others. Also, the stacked double junction circulator device uses a single magnet, which needs to be magnetized. The stacked double junction circulator device offers significant advantages regarding installation requirements on the customer side (e.g., reduced space requirement, surface mountable component, improved integration capabilities). The ferrites can be operated above or below ferromagnetic resonance depending upon frequency range, bandwidth, and power handling requirements.

The stacked double junction circulator device uses a biased below ferromagnetic resonance approach that is commonly used for higher frequency devices. The reduced magnitude of the required static magnetic field allows the use of the single magnet, preferably Samarium-Cobalt (SmCo) magnet that is conducive to solder reflow operations. The stacked double junction circulator device does not need to have an additional return path (e.g., a steel housing) to fully saturate the ferrites and establish the required bias field since the bias field level for an operation below ferromagnetic resonance is low. The elimination of the additional return path also helps to reduce the size of the stacked double junction circulator. The stacked double junction circulator device can achieve double junction functionality with significant reduced size and costs.

In some variations, the front-end module 200 may include one or more T/R building blocks in a BGA package. In other words, a single T/R building block or multiple T/R building blocks can be incorporated into a single surface mount front-end module.

FIG. 4 is a diagram showing multiple building blocks on a single laminated circuit board in a BGA package according to one aspect of the disclosure. As shown in FIG. 4, a front-end module 400 includes multiple building blocks 402A-D mounted on a single laminated circuit board 411. The multiple building blocks 402A-D are included in a BGA package. Each building block may include a circulator embedded within the single laminated circuit board 411. Each building block may also include its corresponding RF amplifiers, transmitting/receiving connectors and transmitting/receiving channels, some of which may be mounted on a mounting surface of the single laminated circuit board 411. Optionally, each building block may also include directional coupler, which may be embedded within the single laminated circuit board 411. The single laminated circuit board 411 has a BGA (not shown) on the opposite side from the building blocks 402A-D. It will be appreciated by those skilled in the art that the number of building blocks may vary.

In some variations, a single BGA package may include one T/R building block as illustrated in FIG. 6A.

In some variations, a single BGA package may also include four T/R building blocks, as illustrated in FIGS. 7A and 7B.

Block diagrams of different implementations for front-end modules are depicted in FIGS. 5A-5C. FIG. 5A shows a front-end module including a single junction circulator according to one aspect of the disclosure. As shown in FIG. 5A, a front-end module 500A includes a single junction circulator 502, which includes three ports, i.e. port 1, port 2, and port 3. In operation, the signal circulates from one port to another port as pointed by an arrow, for example, circulates, in a clockwise direction, from port 2 to port 3, then to port 1, or from port 1 to port 2, then to port 3. The front-end module 500A may include Tx amplifiers placed between the transmitter or Tx and circulator 502 for amplification of transmitting signals from the transmitter or Tx. The Tx amplifier may be a single power amplifier, or by cascading one or more driver amplifiers before the power amplifier. For example, in FIG. 5A, the Tx amplifier may include a driver amplifier 517 and a high-power amplifier 515. The driver amplifier 517 receives a signal from the Tx and outputs an amplified signal that is input into the high-power amplifier 515 that outputs a high-power Tx signal as input to port 1 of the single junction circulator 502, which provides output via port 2 to an antenna interface or a connector to antenna (labeled as “Ant”). The Tx signal may be amplified in order to output a high-power Tx signal. Traditionally, power amplifier refers to any amplifier that outputs high power. However, the amplification of the power amplifier may still be limited to 100 times (100×) or 1000 times (1000×) amplification. In many cases, the input Tx signal may be so weak that the Tx signal may need 1,000,000 times amplification. Unfortunately, in many cases, no single amplifier can amplify the signal as much as desired to provide a target Tx output power. As such, the driver amplifier may be added before the power amplifier. For instance, a power amplifier amplifies the signal 1000 times (1000×). For an output of 10 W, the input needs to be 0.01 W. However, 0.01 W is still a very high value. Thus, another amplifier may be added to amplify the signal, e.g., 1000 times before the power amplifier. Therefore, the input Tx signal can be 0.00001 W, which is a relatively small value.

In some variations, a driver amplifier may be added before a power amplifier.

In some variations, two or more driver amplifiers may be added before a power amplifier.

The front-end module 500A may also include Rx amplifier 509 placed between the signal receiver Rx and the circulator 502. The Rx amplifier 509 may be a low noise amplifier for low noise amplification of RF signals received from an antenna. The front-end module 500A may also include a limiter 511 for limiting high-power RF signals received from an antenna.

The limiter 511 is a device used in RF circuits to protect sensitive components, such as RX amplifiers, from damage caused by high-intensity RF (HIRF) signals. The limiter 511 works by limiting the amplitude of incoming RF signals to a safe level, preventing excessive voltages or currents that may harm the front-end module.

The low-noise amplifier 509 is an RF amplifier designed to amplify weak signals with minimal addition of RF noise. The low-noise amplifier 509 may be the first active component in a receive chain. The low-noise amplifier 509 amplifies the RF signal before significant noises from subsequent stages are introduced. The low-noise amplifier 509 can improve the overall Signal-to-Noise ratio performance of the front-end module.

When the antenna provides a receiving signal to the circulator 502 via the antenna interface or connector to antenna (labeled as “Ant”), the circulator 502 outputs the receiving signal to the limiter 511 and then low noise amplifier 509, which outputs to a signal receiver (Rx).

The front-end module 500A may include uni-directional or bi-directional couplers 513 between the port 2 of circulator 502 and the connector to antenna (labeled as “Ant”) or the antenna interface, and can be used for monitoring Tx and Rx power levels or for calibration purposes.

FIG. 5B shows a front-end module including one circulator of a double junction circulator in a receiving path according to one aspect of the disclosure. As shown in FIG. 5B, a front-end module 500B may include a double junction circulator 504, which includes a first circulator 504A and a second circulator 504B. When an antenna provides a receiving signal to the first circulator 504A of the double junction circulator 504 via an antenna interface (labeled as “Ant”), the first circulator 504A outputs a receiving signal to the limiter 511 and then low noise amplifier 509, which outputs to the signal receiver (Rx) in a receiving path or receiving channel 514. A bi-directional coupler 513 connects between the first circulator 504A and the antenna interface (labeled as “Ant”) for monitoring the power.

The front-end module 500B uses two circulators 504A and 504B rather than one circulator, which helps fully protect both the receiver (Rx) and the transmitter (Tx) from high-intensity RF signals. The first circulator 504A includes three ports, i.e. port 1A, port 2A, and port 3A. In operation, the signal circulates from one port to another port as pointed by an arrow, for example, circulates, in a clockwise direction, from port 1A to port 2A, then to port 3A. The second circulator 504B includes three ports, i.e. port 1B, port 2B, and port 3B. In operation, the signal circulates from one port to another port as pointed by an arrow, for example, circulates, in a clockwise direction, from the first port 1B to the second port 2B, then to the third port 3B. The operation mechanism is as follows. When a high-intensity RF signal coming from the antenna via the antenna interface (labeled as “Ant”) enters the receiving path 514, the high-intensity RF signal can go through the first circulator 504A, then to the limiter 511, which can activate, and reflect all the high-intensity RF energy back, thus protect the low-noise amplifier 509. The reflected energy enters the first circulator 504A again via its third port 3A, and passes to the second port 2B of the second circulator 504B. Then, the second circulator 504B passes the reflected energy from the second port 2B into a resistive termination 505 via the third port 3B, which absorbs all the excess power. The front-end module 500B allows the reflected power from the limiter 511 to be absorbed by the resistive termination 505, and does not get into the Tx amplifiers including Tx high-power amplifier 515 and driver amplifier 517, which may get damaged when power from outside is received. The two circulators 504A and 504B may help fully protect both the receiver (Rx) and the transmitter (Tx) from high-intensity RF signals.

FIG. 5C shows a front-end module including one circulator of a double junction circulator in a transmitting path according to one aspect of the disclosure. As shown in FIG. 5C, a front-end module 500C may include a double junction circulator 506 that includes a first circulator 506A and a second circulator 506B. The first circulator 506A includes three ports, i.e. port 1A, port 2A, and port 3A. In operation, the signal circulates from one port to another port as pointed by an arrow, for example, circulates, in a clockwise direction, from port 2A to port 3A, then to port 1A or circulates from port 1A to port 2A, then port 3A. The second circulator 506B also includes three ports, i.e. port 1B, port 2B, and port 3B. In operation, the signal circulates from one port to another port as pointed by an arrow, for example, circulates, in a clockwise direction, from the second port 2B to the third port 3B, then to the first port 1B or circulates from port 1B to port 2B, then port 3B. A transmitter (Tx) is outside the RF end module 500C and provides an input into a driver amplifier 517, which outputs a signal that is input into a high-power amplifier 515 that outputs a transmitting signal as input to the first circulator 506A of the double junction circulator 506 in a transmitting path or transmitting channel 516, which provides an output to an antenna via an antenna interface (labeled as “Ant”) connected to RF output of the unidirectional or bi-directional coupler 513. The front-end module 500C may also include a termination feature 507 coupled to the second circulator 506B.

The front-end module 500C operates more or less in the same way as the front-end module 500B. Assume a high-intensity RF signal enters from the antenna, the high-intensity RF signal hits the port 2A of the first circulator 506A. The high-intensity RF signal is diverted into the third port 3A of the first circulator 506A and enters the first port 1B of the second circulator 506B. The high-intensity RF signal is diverted to the third port 3B of the second circulator 506B and goes to a limiter 511. Then, the limiter 511 is activated and all of its energy is reflected back to the second port 2B of the second circulator 506B, which diverts the high-intensity RF signal to the third port 3B of the second circulator 506B, which is connected to the termination feature 507 configured to absorb all the energy such that no high-intensity RF signal is sent back to the Tx power amplifiers including amplifiers 515 and 517. Therefore, the front-end module 500C protects the Tx power amplifiers from the high-intensity RF signals.

The front-end module 500A, 500B, or 500C may include various components mounted on a laminated circuit board, as illustrated in FIG. 6A and 7A-7B. The front-end modules 500A, 500B, or 500C may also include some components embedded within a laminated circuit board. For example, a circulator may be embedded within the laminated circuit board, as illustrated in FIG. 6B. Also, a directional coupler may also be embedded within the laminated circuit board, as illustrated in FIG. 6B. Other components, such as power amplifiers, may also be embedded in the laminated circuit board. A first mounting surface of the front-end module 500A, 500B, or 500C may be configured to receive SMD, chip and wire components, magnets, and RF connectors for the antenna, for example, as illustrated in FIGS. 6A and 7A-7B. A second mounting surface of the front-end module 500A, 500B, or 500C may contain a BGA as illustrated in FIG. 8. The second mounting surface is opposite to the first mounting surface. Some active or passive functions may be embedded within the laminated circuit board.

FIG. 6A is a top layout view of an RF front-end module including a circulator according to one aspect of the disclosure. As shown in FIG. 6A, a front-end module 600 may include multiple components on a laminated circuit board 201. For example, the front-end module 600 may include a circulator 602 embedded within a laminated circuit board, such as a stacked double junction circulator. The front-end module 600 may also include a receiver (Rx) 604 below the circulator 602 near a lower left corner. The front-end module 600 may also include a transmitter (Tx) 606 near a lower right corner. The front-end module 600 may also include a directional coupler 608 and a connector to antenna 615 near an upper right corner.

Also, as shown in FIG. 6A, the circulator 602 is connected to the directional coupler 608. The circulator 602 is also coupled to the receiver (Rx) 604 via limiter 610 and connection 612. The circulator 602 is also coupled to the transmitter (Tx) 606 via power amplifier 613 and connection 614. The front-end module 600 may include some additional components, such as resistors and capacitors. It will be appreciated by those skilled in the art that the arrangement of these components may vary on the laminated circuit board.

FIG. 6B is a cross-sectional view of a laminated circuit board of the RF front-end module of FIG. 6A including an embedded double junction circulator according to one aspect of the disclosure. As shown in FIG. 6B, the laminated circuit board 201 has a stackup including the double junction circulator 602 embedded on its left side and the directional coupler 608 embedded on its right side. The laminated circuit board 201 may include ten conductive layers L1-L10 and nine dielectric layers D1-D9 that are interleaved between the conductive layers L1-L10.

The double junction circulator 602 includes first and second circulators 602A and 602B, which include first and second ferrites 604A-604B, respectively, and first and second junction circuits 603A and 603B, respectively. The first ferrite 604A is on the top of ground layer L5. The second ferrite 604B is under the bottom of ground layer L6. The first junction circuit 603A is on top of the first ferrite 604A and is in L4. The second junction circuit 603B is under the bottom of the second ferrite 604B and is in L7.

The laminated circuit board 201 may include ten conductive layers L1-L10. Sarting from a top mounting surface 611 now, L1 may have traces connecting to surface mount devices or wire bond components, such as amplifiers, connectors to antenna, among others. L2-L3, L5-L6, and L8-L9 may be ground layers or inner routing layers. Referring to the middle of the laminated circuit board 201 now, L4 and L7 may include first and second junction circuits 603A and 603B. The circuit trace may be made from copper clad layers that come as part of the printed circuit board panels. Referring to a bottom mounting surface 621 of the laminated circuit board 201 now, L10 may have BGA, which may connect to traces of another PCB.

The laminated circuit board 201 may also include blind vias labeled as “A” which are formed by back drilling from the top mounting surface 611 or from the bottom mounting surface 621 of the laminated circuit board.

Referring to the right side of FIG. 6B now, uni-directional, or bi-directional couplers 608 can be constructed using microstrip or stripline technologies to create input/output ports useful to monitor Tx power, Rx power, high-intensity RF power, or serve as calibration paths.

A permanent magnet may be used to provide the static bias field for the operation of the circulator. Permanent magnets may be attached to the top of the laminated circuit board.

In some variations, additional components, such as passive and/or active components, may also be integrated within the laminated circuit board 201.

In some variations, additional components, such as filters, may also be embedded within the laminated circuit board 201.

In some variations, the circulator may be a stacked double junction circulator, which saves space. In some variations, a single ferrite per junction or per circulator may be used.

In some variations, the number of ferrites in the circulator may vary. When the number of ferrites increases, the strength of the magnet also has to increase, which typically results an increase in the size of the magnet and thus increases the volume of the front-end module.

The ferrites may be operated below Ferromagnetic Resonance (FMR). The static magnetic bias field may be provided by magnets that can withstand reflow temperatures without degradation in field output, e.g., Samarium-Cobalt magnets. A relatively strong permanent magnet, such as rare earth permanent magnet, may ensure that the ferrites are saturated and magnetically biased to an appropriate level.

The ferrites or magnets may be selected based on operation frequency and power handling requirements. The half power ferromagnetic resonance linewidth ΔH and spin wave linewidth ΔHk may be selected to reduce an insertion loss at a specified power level. A ferrite material with an appropriate saturation magnetization 4πMs may be selected according to frequency ranges and bandwidths.

The front-end module may include multiple building blocks on a single laminated circulator board. FIG. 7A is a top view of an RF front-end module including four building blocks configured for four antennas according to one aspect of the disclosure. As shown in FIG. 7A, a front-end module 700 may include four building blocks 701 that are built on a single laminated circuit board 704 which has a top surface or a SMD mounting surface 702 and a bottom surface 703 opposite to the top surface 702. Each building block 701 may include a double junction circulator 703 embedded in the laminated circuit board 704, similar to that show in FIG. 6A. The front-end module 700 is a surface mount device. Permanent magnets 706 may be attached or bonded to the laminated circuit board. Transmitting and/or receiving connectors 708 may also be mounted on surface of the laminated circuit board 701. The transmitting and/or receiving connectors 708 are configured to connect to antenna.

FIG. 7B is a perspective view of the RF front-end module of FIG. 7A including four connectors configured for the four antennas according to one aspect of the disclosure. As shown in FIG. 7B, four permanent magnets 706 may be attached or bonded to the SMD mounting surface 702 of the laminated circuit board 704. The four permanent magnets 706 are used to bias respective double junction circulators 703 embedded in the laminated circuit board 704, for example, four double junction circulators. Each of the four double junction circulators 703 and respective ferrites are located under one of the respective magnets 706 and embedded within the laminated circuit board 704.

Also, as shown in FIG. 7B, four connectors 708 (e.g., blind-mate connectors) may be attached to the SMD mounting surface 702. The connectors 708 may be used to provide receiving and transmitting signals to radiating elements of antenna. The receiving and transmitting signals may be routed through RF-matched BGA connections. In some variations, other routing schemes may be used.

In some variations, the magnets may be replaced by any suitable biasing element provided by the end application, for example, a solenoid or some other suitable biasing means that provides the functionality provided by the magnets.

The front-end module is a surface mount component that enables common solder reflow profiles. FIG. 8 is a perspective view showing BGA on the opposite side of the laminated circuit board of FIG. 7B from surface mount device (SMD) components and wire components according to one aspect of the disclosure. As shown in FIG. 8, a BGA 802 with balls is on the bottom surface 703 of the laminated circuit board 704 to connect to a PCB. On the top surface or SMD mounting surface 702 of the laminated circuit board 704, four magnets 706 are attached and four connectors 708 are configured to attach to four antennas, respectively.

FIG. 9 is a stacked double junction circulator for use in the RF front-end module of FIG. 6B according to one aspect of the disclosure. A stacked double junction circulator device 900 has an asymmetric stripline implementation including a permanent magnet 902 on a top. The stacked double junction circulator device 900 may include eleven layers including six conductive layers interleaved with five dielectric layers. Outer conductive layers 910A and 910D realize ground planes of an asymmetric stripline configuration along with ground layers at the center 910B and 910C, which are separated by a middle dielectric layer 911 in between. Conductive layers or metal layers 908A and 908B are RF circuit traces for the circulator. The outer conductive layer 910A and the conductive layer 908A are separated by a lower dielectric layer 912A in between. Similarly, the outer conductive layer 910D and the conductive layer 908B is separated by an upper dielectric layer 912B in between. Dielectric layer 906A is between conductive layer 908A and conductive layer 910B while dielectric layer 906B is between conductive layer 908B and conductive layer 910C. The dielectric layers 906A and 906B have through-cavities or openings to receive ferrite elements 904A and 904B. Various electric connections are made by metallized vias between conductive layers.

The permanent magnet 902 may be bonded to the outside of the package, in one scenario, on the same plane as other SMD and chip-and-wire components. For example, the permanent magnet 902 that may be bonded to the upper or top ground plane 910D to provide the necessary magnetic biasing field to the ferrite elements.

The stacked double junction circulator device 900 also includes four RF ports, i.e., port 1 (P1), port 2 (P2), port 3 (P3), and port 4 (P4). The RF ports P1, P2, P3, and P4 of the stacked double junction circulator device may be arranged for simplified internal routing.

In some variations, the stacked double junction circulator device may use a single ferrite or a single ferrite element for each of two junction circuits.

In some variations, the stacked double junction circulator may include two or more ferrite elements depending upon the need.

In some variations, the circulator may include the number of ferrites that equals the number of junction circuits. For example, the circulator may include two ferrite elements and two junction circuits. The circulator may also include three ferrite elements and three junction circuits. The circulator may include four ferrite elements and four junction circuits.

In some variations, the circulator may include the number of ferrites that does not equal the number of junction circuits. For example, the circulator may include a single junction circuit and two ferrites. In this variation, the number of junction circuits does not equal the number of junction circuits.

The stackup of the laminated circuit board is built from the bottom up. Also, the ferrite is inserted into a dielectric layer before another dielectric layer is added. All layers are laminated together afterwards.

The ferrite elements or ferrite disks can be biased below ferromagnetic resonance. The ferrite elements are saturated in the presence of the biasing magnetic field. The biasing magnet provides the necessary static magnetic field inside the ferrite element(s). The flux lines are closed through air and no additional housing structures are necessary for an operation below ferromagnetic resonance. In order to improve the magnetic shielding of the device and/or to better utilize the permanent magnet, ferromagnetic return path structures may be employed. The design works at frequency ranges conducive for a below ferromagnetic resonance operation. The above ferromagnetic resonance operation is conceivable but may require additional magnetic biasing elements like a return path structure, among others.

The disclosed front-end module may be used for AESA systems, either for radar or communication purposes.

### Fabrication of Front-End Module

Those skilled in the art will understand that the surface mountable front-end module including a laminated circuit board with embedded circulators may be mounted on any suitable printed circuit board manufacturing techniques.

The disclosure provides a manufacturing process description for fabricating the surface mountable front-end module having the laminated circuit board embedded with circulators. The manufacturing process of the laminated circuit board uses conventional PCB procedures. Layers can be sequentially stacked to have a stripline structure or other forms of transmission lines.

The manufacturing process uses dielectric layers that have conductive layers on one or both sides of each dielectric layer. The conductive layers can be etched to form junction circuits or ground planes or ground layers. For example, the junction circuits may be formed on the dielectric layers by etching using standard photolithography techniques.

Ferrites can be inserted within designated pockets or openings during stacking of a particular ferrite layer before other layers are stacked on the top of the ferrite layer. The manufacturing process also includes embedding ferrites into dielectric layers that are laminated.

The multiple layers of the laminated circuit board can be bonded using standard PCB bonding processes, such as fusion bonding or by using prepreg materials. The manufacturing process also includes bonding the dielectric layers by fusion bonding or bonding the dielectric layers using a liquid resin or prepreg materials.

After lamination of the multiple layers or stackup, drilling and plating processes may follow along with solder mask application. Plating may be conducive to SMD and chip-and-wire mounting if needed.

The laminated circuit board includes plated through-holes or vias and/or blind vias that realize RF connections and provide mode-suppression and isolation features. These plated through-holes or vias may also provide a thermal path. Additional conductive layers can be incorporated into the laminated circuit board for DC power, signal routing, and RF circuit traces. These laminated layers can be stacked to generate an overall thickness conducive to the ferrite height.

The laminated circuit board with the embedded circulators may be fabricated using the fabrication method for the single junction circulator as disclosed in U.S. Pat. No. 8,183,952, entitled “SURFACE MOUNTABLE CIRCULATOR”, by Graeme Bunce et al, issued on May 22, 2012, which is incorporated by reference in its entirety.

The laminated circuit board including the embedded circulators may also be fabricated using the method for fabricating a stacked double junction circulator as disclosed in U.S. patent application Ser. No. 18/629,042, entitled “DESIGN OF STACKED DOUBLE JUNCTION CIRCULATOR DEVICE AND METHODS FOR FABRICATION”, by Thomas Lingel et al, filed on Apr. 8, 2024, which is incorporated by reference in its entirety. In particular, the transitions between the two junction circuits and external interfaces are carefully designed to achieve a good match.

Multiple packages or multiple front-end modules may be integrated on larger PCB panels that can be singulated or separated later. After the parts have been singulated, active and passive components as well as the permanent magnets can be mounted to the top surface of the laminated circuit board by using standard SMD, epoxy or chip and wire processes. The entire package may be shielded and mechanically covered using common packaging approaches, e.g., using metal cover, glob top, among others.

For example, a package may include four front-end modules integrated may have a size of roughly 30 mm by 30 mm. Many of these quad-front-end modules or packages can be arrayed on a panel, which may have a size of about 12 inch by 18 inch as an example.

Laminated circuit boards may be produced using high levels of automation. Thus, the fabrication is low-cost and suited for high-volume manufacturing.

The laminated circuit board may be fabricated using an example approach as below. Referring to FIG. 9 now, the ferrite elements become embedded and integral parts of the interior dielectric layers 906A and 906B in the double junction circulator device 900. Any suitable process for bonding the dielectric layers 906A, 906B, 912A and 912B, and ground layers or planes 910A, 910B, 910C, and 910D together may be employed. In some variations, the dielectric layers may be provided with metallization from vendors. The metallization means that ground layers are bonded to the dielectric layers.

In some variations, the dielectric layers may be fabricated using a suitable dielectric material configured to support the junction circuits. For example, dielectric layers 912A and 912B may be formed using dielectric materials suitable for printed circuit boards (PCBs). As such, the dielectric layers 912A and 912B may be fabricated using suitable materials such as polytetrafluoroethylene (PTFE), among others. The junction circuits 908A and 908B may be formed on one side of the dielectric layers 912A and 912B using PCB manufacturing techniques. The dielectric layers may be provided with conductive layers on two opposite surfaces. The conductive layers can be etched to form the junction circuits.

In some variations, the junction circuits 908A and 908B may be formed of any suitable conductive material, such as gold (Au), silver (Ag), copper (Cu), among others. The junction circuits include circuit traces.

In some variations, the dielectric layers 906A and 906B may be fabricated using a suitable dielectric material, such as suitable for printed circuit boards (PCBs). For example, the dielectric layers may be fabricated using polytetrafluoroethylene (PTFE), or a PTFE composite board. Depending on its function within the laminated multi-layer assembly, the PTFE composite board may include a copper layer disposed over the PTFE dielectric layer. The copper layer may function as a ground plane. The multi-layer PTFE composite board can be created by bonding the multi-layer laminates.

In some variations, the dielectric layers may be fabricated using a ceramic material.

In some variations, the junction circuits may also be formed by a screen-printing process.

In some variations, the ground planes may also be printed or etched upon the dielectric layers using any suitable circuit trace process.

The RF connections for the front-end module can be routed to the top or bottom surface. The BGA is used for routing to Tx or Rx, while the blind mate connectors are used for routing to the antenna. It will be appreciated by those skilled in the art that other routing configurations may be used.

In a typical production process, the dielectric layers and the ground planes or layers are stacked and laminated, the ferrite elements are embedded within the device during the stacking operation. Afterwards, the magnets may be bonded to the exterior of the part in the manner depicted in FIG. 7B. Then, the circulator may be magnetically tuned and evaluated.

Clause 1. A surface mounting device for transmitting or receiving signals from one or more antennas, the surface mounting device comprising: one or more circulators embedded within a laminated circuit board, the one or more circulators coupled to the one or more antennas and serving as duplexers, one or more magnets attached to a first mounting surface of the laminated circuit board; one or more radio frequency (RF) amplifiers coupled between the one or more circulators and one or more transmitters, one or more circuit components coupled between the one or more circulators and one or more receivers; and ball grid array (BGA) solder balls on a second mounting surface of the laminated circuit board opposite to the first mounting surface.

Clause 2. The surface mounting device of clause 1, wherein the one or more RF amplifiers are attached to the first mounting surface or embedded within the laminated circuit board.

Clause 3. The surface mounting device of clause 1, wherein the one or more RF amplifiers comprise power amplifier and/or driver amplifier.

Clause 4. The surface mounting device of clause 1, wherein the one or more circuit components are attached to the first mounting surface or embedded within the laminated circuit board.

Clause 5. The surface mounting device of clause 1, wherein the one or more circuit components comprise low noise amplifier and/or limiter.

Clause 6. The surface mounting device of clause 1, wherein the one or more magnets comprise one of Ceramic magnets, Samarium-Cobalt (SmCo) magnets, Aluminum-Nickel-Cobalt (AlNiCo) magnets, or Neodymium-Iron-Boron (NdFeB) magnets.

Clause 7. The surface mounting device of clause 1, further comprising one or more RF connectors attached to the first mounting surface of the laminated circuit board and configured to receive signals or transmit signals from the one or more antennas.

Clause 8. The surface mounting device of clause 1, wherein the one or more circulators comprise surface mountable single junction circulators.

Clause 9. The surface mounting device of clause 1, wherein the one or more circulators comprise stacked double junction circulators.

Clause 10. The surface mounting device of clause 9, further comprising a termination feature.

Clause 11. The surface mounting device of clause 10, wherein the termination feature is embedded within the laminated circuit board.

Clause 12. The surface mounting device of clause 10, wherein the termination feature is mounted on the first mounting surface of the laminated circuit board.

Clause 13. The surface mounting device of clause 1, wherein the surface mounting device is a surface mount module on a printed circuit board.

Clause 14. The surface mounting device of clause 1, wherein the surface mounting device is suitable for radio frequency applications.

Clause 15. The surface mounting device of clause 14, wherein the radio frequency applications comprise active electronically scanned array (AESA) applications.

Clause 16. A method for fabricating a surface mounting device for transmitting or receiving signals from one or more antennas, the method comprising: embedding one or more circulators embedded within a laminated circuit board comprising a plurality of dielectric layers interleaved with a plurality of conductive layers, the one or more circulators coupled to the one or more antennas and serving as duplexers; attaching one or more magnets to a first mounting surface of the laminated circuit board; forming one or more radio frequency (RF) amplifiers coupled between the one or more circulators and one or more transmitters; and forming one or more circuit components coupled between the one or more circulators and one or more receivers,, wherein ball grid array (BGA) solder balls are formed on a second mounting surface of the laminated circuit board opposite to the first mounting surface.

Clause 17. The method of clause 16, further comprising attaching the one or more circuit components to the first mounting surface or embedding the one or more circuit components within the laminated circuit board.

Clause 18. The method of clause 16, further comprising attaching the one or more RF amplifiers to the first mounting surface or embedding the one or more circuit components within the laminated circuit board.

Clause 19. The method of clause 16, further comprising embedding one or more directional coupler within the laminated circuit board, wherein the one or more directional coupler is coupled between the one or more circulators and the one or more antennas.

Clause 20. The method of clause 16, further comprising bonding two adjacent dielectric layers using fusion bonding or using a liquid resin or prepreg material.

Any ranges cited herein are inclusive. The terms “substantially” and “about” used throughout this specification are used to describe and account for small fluctuations. For example, they can refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%.

Having described several embodiments, it will be recognized by those skilled in the art that various modifications, alternative constructions, and equivalents may be used without departing from the spirit of the invention. Additionally, a number of well-known processes and elements have not been described in order to avoid unnecessarily obscuring the invention. Accordingly, the above description should not be taken as limiting the scope of the invention.

Those skilled in the art will appreciate that the presently disclosed embodiments teach by way of example and not by limitation. Therefore, the matter contained in the above description or shown in the accompanying drawings should be interpreted as illustrative and not in a limiting sense. The following claims are intended to cover all generic and specific features described herein, as well as all statements of the scope of the method and system which, as a matter of language, might be said to fall therebetween.

What is claimed is:

1. A surface mounting device for transmitting or receiving signals from one or more antennas, the surface mounting device comprising:
one or more circulators embedded within a laminated circuit board, the one or more circulators coupled to the one or more antennas and serving as duplexers,
one or more magnets attached to a first mounting surface of the laminated circuit board;
one or more radio frequency (RF) amplifiers coupled between the one or more circulators and one or more transmitters,
one or more circuit components coupled between the one or more circulators and one or more receivers; and
ball grid array (BGA) solder balls on a second mounting surface of the laminated circuit board, the second mounting surface being opposite to the first mounting surface.

2. The surface mounting device of claim 1, wherein the one or more RF amplifiers are attached to the first mounting surface or embedded within the laminated circuit board.

3. The surface mounting device of claim 1, wherein the one or more RF amplifiers comprise power amplifier and/or driver amplifier.

4. The surface mounting device of claim 1, wherein the one or more circuit components are attached to the first mounting surface or embedded within the laminated circuit board.

5. The surface mounting device of claim 1, wherein the one or more circuit components comprise a low noise amplifier and/or limiter.

6. The surface mounting device of claim 1, wherein the one or more magnets comprise one of Ceramic magnets, Samarium-Cobalt (SmCo) magnets, Aluminum-Nickel-Cobalt (AlNiCo) magnets, or Neodymium-Iron-Boron (NdFeB) magnets.

7. The surface mounting device of claim 1, further comprising one or more RF connectors attached to the first mounting surface of the laminated circuit board and configured to receive signals or transmit signals from the one or more antennas.

8. The surface mounting device of claim 1, wherein the one or more circulators comprise single junction circulators.

9. The surface mounting device of claim 1, wherein the one or more circulators comprise stacked double junction circulators.

10. The surface mounting device of claim 9, further comprising a termination feature.

11. The surface mounting device of claim 10, wherein the termination feature is embedded within the laminated circuit board.

12. The surface mounting device of claim 10, wherein the termination feature is mounted on the first mounting surface of the laminated circuit board.

13. The surface mounting device of claim 1, wherein the surface mounting device is a surface mount module on a printed circuit board.

14. The surface mounting device of claim 1, wherein the surface mounting device is suitable for radio frequency applications.

15. The surface mounting device of claim 14, wherein the radio frequency applications comprise active electronically scanned array (AESA) applications.

16. A method for fabricating a surface mounting device configured for transmitting or receiving signals from one or more antennas, the method comprising:
embedding one or more circulators within a laminated circuit board comprising a plurality of dielectric layers interleaved with a plurality of conductive layers, the one or more circulators coupled to the one or more antennas and serving as duplexers;
attaching one or more magnets to a first mounting surface of the laminated circuit board;
forming one or more radio frequency (RF) amplifiers coupled between the one or more circulators and one or more transmitters; and
forming one or more circuit components coupled between the one or more circulators and one or more receivers, wherein ball grid array (BGA) solder balls are formed on a second mounting surface of the laminated circuit board opposite to the first mounting surface.

17. The method of claim 16, further comprising attaching the one or more circuit components to the first mounting surface or embedding the one or more circuit components within the laminated circuit board.

18. The method of claim 16, further comprising attaching the one or more RF amplifiers to the first mounting surface or embedding the one or more circuit components within the laminated circuit board.

19. The method of claim 16, further comprising embedding one or more directional coupler within the laminated circuit board, wherein the one or more directional coupler is coupled between the one or more circulators and the one or more antennas.

20. The method of claim 16, further comprising bonding two adjacent dielectric layers using fusion bonding or a liquid resin or prepreg material.
